(19) United States
(12) Patent Application Publication
(10) Pub. No.: US 2012/0038402 A1
(43) Pub. Date: Feb. 16, 2012

(54) Clock generation circuit and electronic apparatus

(75) Inventor: Naoki Takahashi, Kanagawa (JP)

(73) Assignee: Sony Corporation, Tokyo (JP)

(21) Appl. No.: 13/067,657

(22) Filed: Jun. 17, 2011

(30) Foreign Application Priority Data
Aug. 10, 2010 (JP) 2010-179383

(51) Int. Cl. H03L 7/06

(52) U.S. Cl. 327/157; 327/158

(57) ABSTRACT

Disclosed herein is a clock generation circuit, including a current-controlled oscillation section including a plurality of delay circuits, which include a plurality of current-controlled delay circuits adapted to delay a signal by a delay amount corresponding to current supplied thereto, connected so as to form a closed loop and adapted to output a clock signal formed by the closed loop; a phase controlling section including a comparator adapted to compare the clock signal with a reference signal and adapted to output controlling current, which varies so as to decrease the phase difference between the clock signal and the reference signal, to the current-controlled delay circuits; and a spread current generation section adapted to supply spread spectrum current of a current value different from that of the controlling current in place of the controlling current to a particular one or ones of the current-controlled delay circuits.

### BACKGROUND

This disclosure relates to a clock generation circuit for generating a clock signal and an electronic apparatus.

In recent years, electronic apparatus utilize a clock signal of a high frequency in order to achieve high speed processing and multifunctioning.

As a clock generation circuit for generating a clock signal, a PLL (Phase Locked Loop) circuit having a VCO (Voltage Controlled Oscillator), a phase comparator, a charge pump and a loop filter is available.

The phase comparator compares a clock signal outputted thereto from the VCO with a reference signal.

The charge pump outputs a voltage corresponding to a phase difference between the clock signal and the reference signal.

The VCO receives an output voltage smoothed by the loop filter as an input thereto and oscillates a clock signal of a frequency corresponding to the smoothed output voltage.

The PLL circuit thereby generates the clock signal synchronized with the reference signal.

As the frequency of the clock signal increases, there is the possibility that an electromagnetic wave arising from the clock signal may be radiated.

Therefore, a DA (Digital to Analog) converter for current is provided, for example, between a voltage-current conversion circuit and a current-controlled oscillation circuit of the VCO. Further, the current DA converter causes the current, which is to be supplied to the current-controlled oscillation circuit, to fluctuate delicately (see, for example, Japanese Patent Laid-Open No. 2004-104655 (hereinafter referred to as Patent Document 1) and Japanese Patent Laid-Open No. 2004-208193 (hereinafter referred to as Patent Document 2)).

With the clock generation circuit, it is possible to spread a frequency spectrum of the clock signal and suppress the peak of electromagnetic radiation by the clock signal.

### SUMMARY

However, in the case where a current DA converter is disposed between a voltage-current conversion circuit and a current-controlled oscillation circuit and causes current itself, which is to be supplied to the current-controlled oscillation circuit, to fluctuate as in the case of Patent Document 1 or 2, the following problems occur.

In Patent Document 1, output current of the voltage-current conversion circuit is supplied as it is to the current DA converter and then supplied to the current-controlled oscillation circuit. In this instance, in order to allow the current DA converter to cause current, which is to be supplied to the current-controlled oscillation circuit, to fluctuate delicately, a great bit number with which an adjustment range of the output current of the voltage-current conversion circuit can be resolved with a desired resolution is required.

In Patent Document 2, two current DA converters are used. Consequently, with the clock generation circuit of Patent Document 2, the total bit number can be reduced from that of Patent Document 1.

However, also with the clock generation circuit of Patent Document 2, in order to smooth the modulation profile of current, it is necessary to finely adjust current to be supplied to the current-controlled oscillation circuit. Therefore, a high resolution is required for the current DA converters.

In this manner, the circuit scale of a current DA converter adopted in a clock generation circuit for spectrum spreading increases in response to the adjustment range of current and the resolution.

In this manner, it is demanded for a clock generation circuit to spread a frequency spectrum of a clock signal suitably while the circuit scale thereof is suppressed.

According to an embodiment of the present disclosure, there is provided a clock generation circuit including a current-controlled oscillation section including a plurality of delay circuits, which include a plurality of current-controlled delay circuits for delaying a signal by a delay amount corresponding to current supplied thereto, connected so as to form a closed loop and adapted to output a clock signal formed by the closed loop, a phase controlling section including a comparator for comparing the clock signal with a reference signal and adapted to output controlling current, which varies so as to decrease the phase difference between the clock signal and the reference signal, to the current-controlled delay circuits, and a spread current generation section adapted to supply spread spectrum current of a current value different from that of the controlling current in place of the controlling current to a particular one or ones of the current-controlled delay circuits.

In the clock generation circuit, to the particular one or ones of the current-controlled delay circuits, spread spectrum current of a current value different from that of controlling current is supplied in place of the controlling current from the spread current generation section.

Therefore, the closed loop which includes the delay circuits including the current-controlled delay circuits generates a clock signal of a frequency different from that in the case where the controlling current is supplied to all current-controlled delay circuits.

Further, since the spread spectrum current is supplied to the particular one or ones of the current-controlled delay circuits, the variation width of the frequency of the clock signal is small in comparison with that in the case wherein the spread spectrum current is applied to all of the current-controlled delay circuits in the closed loop.

Therefore, the spread current generation section can adjust the frequency of the clock signal with a small resolution to spread the spectrum irrespective of the magnitude of the current adjustment range.

As a result, with the clock generation circuit, the circuit scale of the spread current generation section can be reduced.

According to another embodiment of the present disclosure, there is provided an electronic apparatus including a clock generation circuit adapted to generate a clock signal having a phase synchronized with that of a reference signal, and an inputted section to which the clock signal is inputted, the clock generation circuit including a current-controlled oscillation section including a plurality of delay circuits, which include a plurality of current-controlled delay circuits for delaying a signal by a delay amount corresponding to current supplied thereto, connected so as to form a closed loop and adapted to output a clock signal formed by the closed loop, a phase controlling section including a comparator for comparing the clock signal with a reference signal and adapted to output controlling current, which varies so as to decrease the phase difference between the clock signal and the reference signal, to the current-controlled delay circuits, and a spread current generation section adapted to supply spread spectrum current of a current value different from that of the controlling current in place of the controlling current to a particular one or ones of the current-controlled delay circuits.

With the clock generation circuit and the electronic apparatus, the frequency spectrum of a clock signal can be spread suitably while the circuit scale the clock generation circuit is suppressed.

The above and other objects, features and advantages of the present disclosure will become apparent from the following description and the appended claims, taken in conjunction with the accompanying drawings in which like parts or elements denoted by like reference symbols.

### BRIEF DESCRIPTION OF THE DRAWINGS

FIG. 1 is a block diagram of a PLL circuit of a clock generation circuit according to a first embodiment of the disclosed technology;

FIG. 2 is a circuit diagram of the PLL circuit of FIG. 1;

FIG. 3 is a circuit diagram of a first current-controlled delay circuit shown in FIG. 1;

FIG. 4 is a circuit diagram of a charge pump shown in FIG. 1;

FIG. 5 is a circuit diagram of a first voltage-current conversion circuit shown in FIG. 1;

FIG. 6 is a circuit diagram of a current DA converter shown in FIG. 1;

FIG. 7 is a block diagram of a PLL circuit of a comparative example;

FIG. 8 is a circuit diagram of a PLL circuit of a clock generation circuit according to a second embodiment;

FIG. 9 is a circuit diagram of a second current-controlled delay circuit shown in FIG. 8;

FIG. 10 is a schematic block diagram of a PLL circuit of a clock generation circuit according to a third embodiment;

FIG. 11 is a circuit diagram of the PLL circuit of FIG. 10;

FIG. 12 is a circuit diagram of a PLL circuit of a clock generation circuit according to a fourth embodiment; and

FIG. 13 is a block diagram of a broadcasting signal reception apparatus according to a fifth embodiment.

### DETAILED DESCRIPTION OF THE PREFERRED EMBODIMENTS

In the following, preferred embodiments of the disclosed technology are described with reference to the accompanying drawings.

The description is given in the following order.

1. First Embodiment (example of a clock generation circuit wherein spread spectrum current is supplied to a particular one or ones of current-controlled delay circuits)

2. Comparative Example (example of a clock generation circuit wherein spread spectrum current is supplied to all current-controlled delay circuits)

3. Second Embodiment (example of a clock generation circuit wherein spread spectrum current and second controlling current are supplied to a particular one or ones of current-controlled delay circuits)

4. Third Embodiment (example of a clock generation circuit wherein a supplying destination of spread spectrum current is changed over between a plurality of current-controlled delay circuits)

5. Fourth Embodiment (example of a clock generation circuit wherein a supplying destination of spread spectrum current and second controlling current is changed over between a plurality of current-controlled delay circuits)

6. Fifth Embodiment (example of an electronic apparatus)

<1. First Embodiment>

Configuration of the PLL Circuit 1

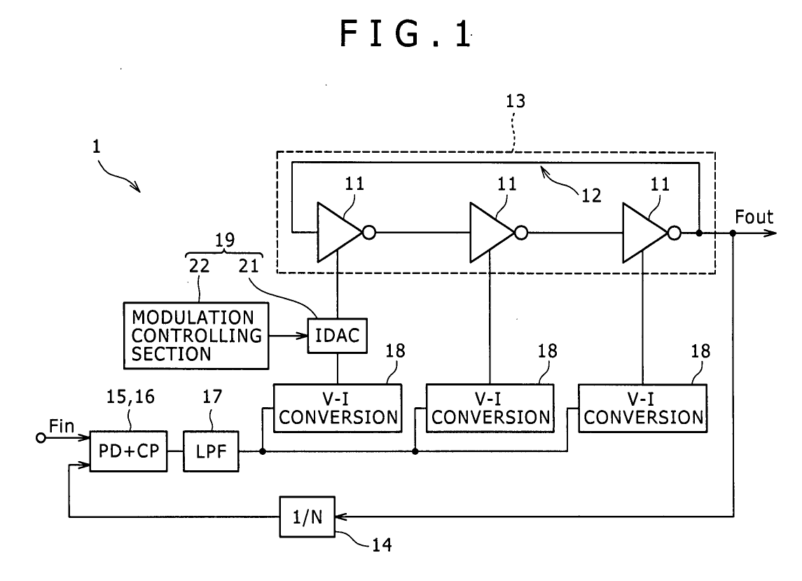

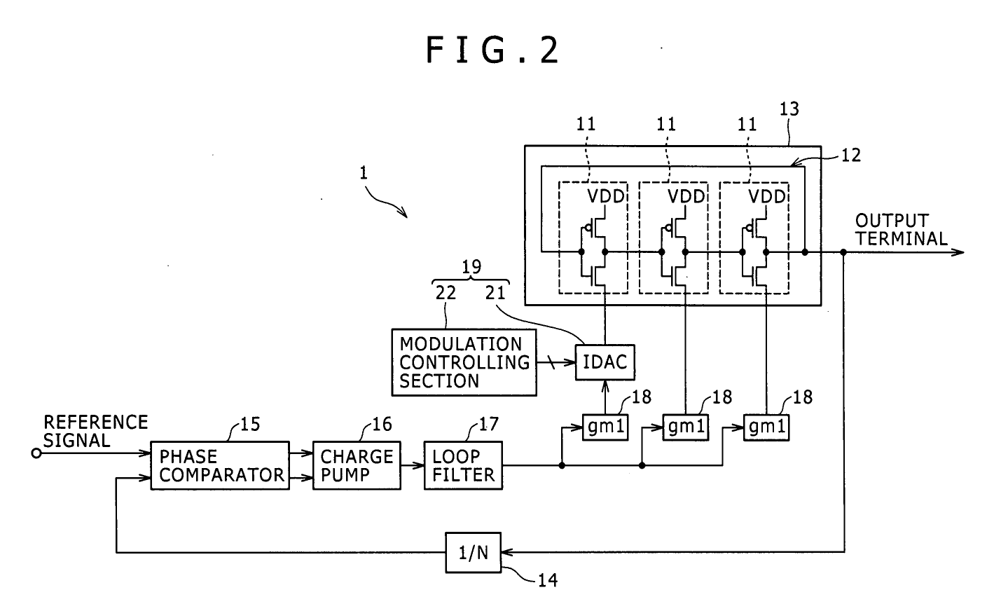

FIG. 1 shows a PLL circuit 1 according to a first embodiment of the disclosed technology, and FIG. 2 shows a circuit configuration of the PLL circuit 1.

Referring to FIGS. 1 and 2, the PLL. circuit 1 generates and outputs a clock signal.

The PLL circuit 1 includes a ring oscillation section 13 having a closed loop 12 of a plurality of first current-controlled delay circuits 11, a frequency dividing circuit 14, a phase comparator 15, a charge pump 16, a loop filter 17, a plurality of first voltage-current conversion circuits 18, and a spread current generation section 19.

The spread current generation section 19 includes a current DA converter 21 and a modulation controlling section 22.

The PLL circuit 1 time-divisionally supplies, to one of the first current-controlled delay circuits 11, first controlling current from a corresponding one of the first voltage-current conversion circuits 18 and spread spectrum current of a current value different from that of the first controlling current.

Further, the PLL circuit 1 supplies, to the remaining ones of the first current-controlled delay circuits 11, the first controlling current from the corresponding first voltage-current conversion circuits 18.

Consequently, the delay time of the clock signal by the closed loop 12 time-divisionally varies in response to a variation of current.

The frequency of the clock signal generated by the ring oscillation section 13 fluctuates delicately at and in the proximity of a desired frequency.

The spectrum of the clock signal spreads to the frequency range of the fluctuation.

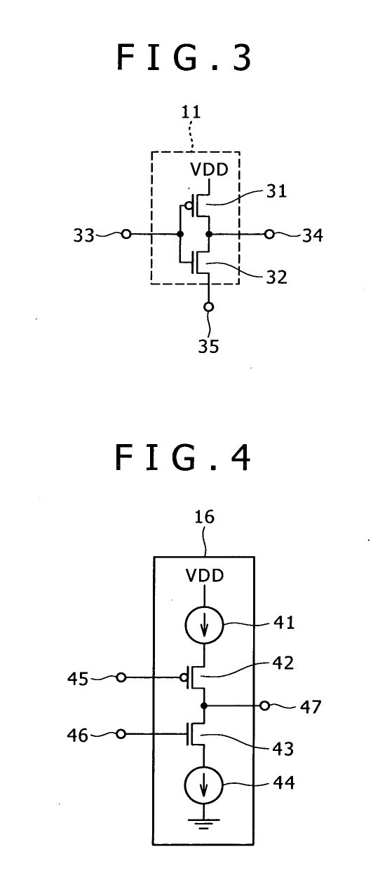

FIG. 3 shows a circuit configuration of a first current-controlled delay circuit 11 shown in FIG. 1.

Referring to FIG. 3, the first current-controlled delay circuit 11 shown delays and outputs a clock signal inputted thereto.

The first current-controlled delay circuit 11 includes a first transistor 31 and a second transistor 32. Further, the first current-controlled delay circuit 11 has an input terminal 33, an output terminal 34, and a first current terminal 35.

The first transistor 31 is, for example, a P channel MOS (Metal Oxide Semiconductor) transistor.

The first transistor 31 is connected at the gate electrode thereof to the input terminal 33 and at the source electrode thereof to a first voltage line (VDD). Further, the first transistor 31 is connected at the drain electrode thereof to the output terminal 34.

The second transistor 32 is, for example, an N channel MOS transistor.

The second transistor 32 is connected at the gate electrode thereof to the input terminal 33, at the source electrode thereof to the first current terminal 35, and at the drain electrode thereof to the output terminal 34.

By the connection scheme described above, the first transistor 31 and the second transistor 32 configure a CMOS structure.

Then, for example, if the input terminal 33 is in the high level state, then the second transistor 32 exhibits an on state and the first transistor 31 exhibits an off state.

Consequently, the second transistor 32 can supply current supplied thereto from the first current terminal 35 to the output terminal 34.

As a result, the output terminal 34 is placed into a low level state.

On the other hand, if the input terminal 33 is in the low level state, then the second transistor 32 exhibits an off state and the first transistor 31 exhibits an on state.

Consequently, the first transistor 31 can supply current supplied thereto from the VDD power supply to the output terminal 34.

As a result, the output terminal 34 is placed into a high level state.

The first current-controlled delay circuit 11 inverts, by a switching operation of the first transistor 31 and the second transistor 32, a signal inputted to the input terminal 33 and outputs the resulting signal from the output terminal 34.

The time after the signal inputted to the input terminal 33 changes until the signal outputted from the output terminal 34 changes is controlled by the switching operation time in response to the current to be supplied to the output terminal 34.

The ring oscillation section 13 generates a clock signal.

The ring oscillation section 13 includes three first current-controlled delay circuits 11 connected in series as seen in FIG. 1.

The output terminal 34 of the first current-controlled delay circuit 11 in the last stage is connected to the input terminal 33 of the first current-controlled delay circuit 11 in the first stage.

Consequently, the closed loop 12 is formed.

In the case where the closed loop 12 is configured from the first current-controlled delay circuits 11 of three stages as shown in FIG. 1, if the output terminal 34 in the last stage exhibits the low level, then the output terminal 34 in the first stage exhibits the high level and the output terminal 34 in the second stage outputs the low level. Therefore, the output terminal 34 in the last stage varies to a high level state.

In this manner, the closed loop 12 formed from the first current-controlled delay circuits 11 of three stages of FIG. 1 generates a clock signal of a period which depends upon the total signal delay time of the first current-controlled delay circuits 11 of the three stages.

The phase comparator 15 is connected to the output terminal 34 of the first current-controlled delay circuit 11 in the last stage of the ring oscillation section 13. Further, a quartz oscillator not shown is connected to the phase comparator 15. The quartz oscillator outputs a reference signal.

To the phase comparator 15, the clock signal generated by the ring oscillation section 13 and the reference signal generated by the quartz oscillator are inputted.

Then, the phase comparator 15 compares the clock signal and the reference signal in phase and outputs a signal representative of the direction and the magnitude of the phase difference between the clock signal and the reference signal.

FIG. 4 shows a circuit configuration of the charge pump 16 shown in FIG. 1.

Referring to FIG. 4, the charge pump 16 includes a charging constant current source 41, a charging transistor 42, a discharging transistor 43 and a discharging constant current source 44. Further, the charge pump 16 has a charging input terminal 45, a discharging input terminal 46 and an output terminal 47.

The charging transistor 42 is, for example, a P channel MOS transistor.

The charging constant current source 41 is connected between the VDD power supply line and the source electrode of the charging transistor 42.

The charging transistor 42 is connected at the gate electrode thereof to the charging input terminal 45 and at the drain electrode thereof to the output terminal 47.

The discharging transistor 43 is, for example, an N channel MOS transistor.

The discharging constant current source 44 is connected between the ground and the source electrode of the discharging transistor 43.

The discharging transistor 43 is connected at the gate electrode thereof to the discharging input terminal 46 and at the drain electrode thereof to the output terminal 47.

The charging input terminal 45 and the discharging input terminal 46 of the charge pump 16 are connected to the phase comparator 15.

A signal generated by the phase comparator 15 is inputted to the charging input terminal 45 and the discharging input terminal 46.

Then, the charge pump 16 outputs a signal in response to a comparison by the phase comparator 15. The signal outputted from the charge pump 16 includes current of a value based on the comparison by the phase comparator 15.

In particular, for example, if the clock signal delays in phase from the reference signal, then the charging input terminal 45 of the charge pump 16 is controlled to the low level.

Consequently, the charging transistor 42 is placed into an on state, and the charge pump 16 supplies charging current from the output terminal 47.

On the other hand, if the clock signal advances in phase from the reference signal, then the discharging input terminal 46 of the charge pump 16 is controlled to the high level.

Consequently, the discharging transistor 43 is placed into an on state, and the charge pump 16 pulls in charging current from the output terminal 47.

If the reference signal and the clock signal are in phase, then both of the charging transistor 42 and the discharging transistor 43 in the charge pump 16 are placed into an off state.

In this instance, the charge pump 16 does not output charging current from the output terminal 47.

In this manner, the charge pump 16 outputs current corresponding to the phase difference between the reference signal and the clock signal.

The loop filter 17 includes, for example, a capacitor.

The capacitor is connected at one electrode thereof to the output of the charge pump 16 and at the other electrode thereof to the ground.

The capacitor is charged with charging current of the charge pump 16.

Consequently, the capacitor generates a voltage like a dc voltage, which is the difference of an ac component from the charging current of the output signal of the charge pump 16.

The loop filter 17 generates a voltage by smoothing the output signal of the charge pump 16.

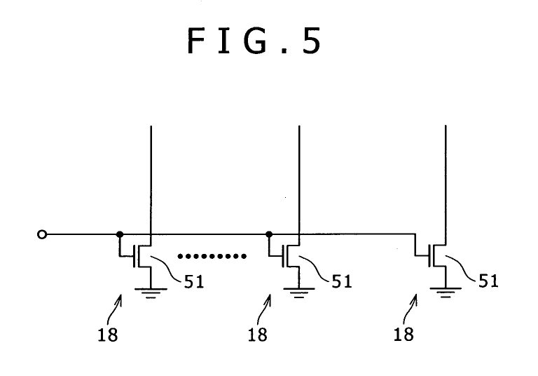

FIG. 5 shows a circuit configuration of a first voltage-current conversion circuit 18 shown in FIG. 1.

Referring to FIG. 5, each first voltage-current conversion circuit 18 includes a current transistor 51.

The current transistor 51 is, for example, an N channel MOS transistor.

The current transistor 51 is connected at the gate electrode thereof to the loop filter 17 and at the source electrode thereof to the ground.

The current transistor 51 is connected at the drain electrode thereof to the source electrode of the second transistor 32 of the first current-controlled delay circuit 11 by a wiring line as seen in FIG. 1.

The current transistors 51 are connected, for example, in a one-by-one corresponding relationship to the first current-controlled delay circuits 11 of the ring oscillation section 13.

Then, the current transistors 51 form channels in response to the voltage smoothed by loop filters 17.

Consequently, each current transistor 51 supplies the first controlling current in response to the smoothed voltage to the second transistor 32 of the first current-controlled delay circuit 11.

As the voltage smoothed by the loop filter 17 increases, the first controlling current increases.

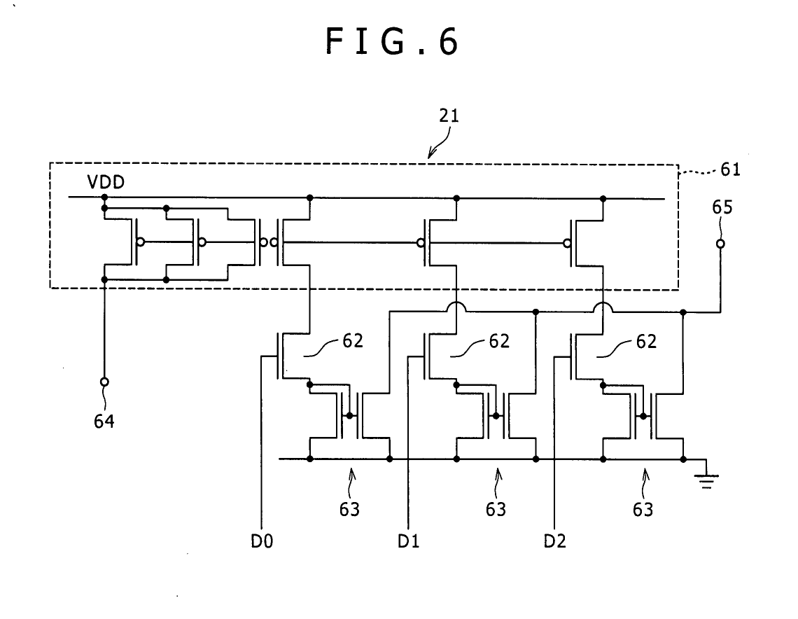

FIG. 6 shows an example of a circuit configuration of the current DA converter 21 shown in FIG. 1.

Referring to FIG. 6, the current DA converter 21 shown includes an input side mirror circuit 61, a plurality of switching transistors 62, and a plurality of output side mirror circuits 63. The current DA converter 21 has an input terminal 64 and an output terminal 65.

Each switching transistor 62 is, for example, an N channel MOS transistor.

The switching transistor 62 is connected at the gate electrode thereof to the modulation controlling section 22.

Each of the output side mirror circuits 63 has, for example, a pair of N channel MOS transistors connected in a current mirror connection.

In order to configure the current mirror connection, the N channel MOS transistors are connected at the source electrode thereof to the ground. The MOS transistor on the input side is connected at the drain electrode thereof to the source electrode of the N channel switching transistor 62. The gates of the N channel MOS transistors are connected to each other. Further, the gate and the drain of the MOS transistor on the input side are connected in diode connection.

Meanwhile, the MOS transistor on the output side of the output side mirror circuit 63 is connected at the drain electrode thereof to the output terminal 65.

The input side mirror circuit 61 has a current mirror structure formed, for example, from a plurality of sets of P channel MOS transistors.

All of the P channel MOS transistors are connected at the source electrode thereof to the VDD power supply line. The gate electrodes of the P channel MOS transistors are connected to each other.

The P channel MOS transistor on the output side is connected at the drain electrode thereof to the drain electrodes of the switching transistors 62.

Further, the P channel MOS transistor on the input side is connected at the drain electrode thereof to the input terminal 64.

The current DA converter 21 is connected at the input terminal 64 thereof to one of the first voltage-current conversion circuits 18 as shown in FIG. 1.

Further, the current DA converter 21 is connected at the output terminal 65 thereof to one of the first current-controlled delay circuits 11 which corresponds to the first voltage-current conversion circuit 18.

The current DA converter 21 is connected between a set of a first voltage-current conversion circuit 18 and a first current-controlled delay circuit 11.

The first controlling current inputted to the input terminal 64 is folded back by the input side mirror circuit 61.

Then, for example, in the case where all of the switching transistors 62 are in an on state, all currents folded back in this manner are inputted to the output side mirror circuits 63 through the switching transistors 62.

The output side mirror circuits 63 fold back the currents.

Output currents of the output side mirror circuits 63 is synthesized at the output terminal 65.

Therefore, the first control current is supplied from the output terminal 65 of the current DA converter 21 to the first current-controlled delay circuit 11.

In the case where a particular one or ones of the switching transistors 62 are in an off state, part of the first controlling current is inputted to corresponding ones of the output side mirror circuits 63. The output side mirror circuits 63 to which the currents are inputted fold back the currents.

Output currents of the output side mirror circuits 63 are synthesized at the output terminal 65.

Therefore, current lower than the first controlling current is supplied from the output terminal 65 of the current DA converter 21 to the first current-controlled delay circuit 11.

The current lower than the first controlling circuit is hereinafter referred to as spread spectrum current.

The spread spectrum current exhibits a current value based on the ratio of those switching transistors 62 which are in an on state and so forth.

In this manner, the current DA converter 21 supplies first controlling current or spread spectrum current to the first current-controlled delay circuit 11 in response to on/off states of the switching transistors 62.

It is to be noted that, in the current DA converter 21 of FIG. 6, the number of P channel MOS transistors on the input side and the number of P channel MOS transistors on the output side in the input side mirror circuit 61 are equal to each other.

Therefore, in the current DA converter 21 of FIG. 6, the current supplied to the first current-controlled delay circuits 11 ranges from 0 ampere in the minimum to the first controlling current to be inputted to the input terminal.

The current supplied from the current DA converter 21 of FIG. 6 to the first current-controlled delay circuit 11 varies discretely within this current range.

In contrast, the number of P channel MOS transistors on the output side of the input side mirror circuit 61 may be greater than the number of P channel MOS transistors on the input side of the input side mirror circuit 61.

Further, the number of the output side mirror circuits 63 and the switching transistor 62 may be increased from that in the current DA converter 21 of FIG. 6.

In the case of those modifications, the current DA converter 21 of FIG. 6 can supply current within a range from 0 ampere to current higher than the first controlling current.

The current higher than the first controlling current can be supplied to the first current-controlled delay circuit 11.

Operation of the PLL Circuit 1

Operation of the PLL circuit 1 having the configuration described above is described below.

In an initial state after power supply to the PLL circuit 1 is started, the modulation controlling section 22 controls all switching transistors 62 of the current DA converter 21 to an on state.

The modulation controlling section 22 outputs a set value for placing all switching transistors 62 into an on state to the current DA converter 21.

In this instance, the current DA converter 21 supplies the first controlling current supplied from the first voltage-current conversion circuits 18 to the first current-controlled delay circuit 11.

To all of the first current-controlled delay circuits 11 which configure the closed loop 12, the first controlling current is supplied.

Therefore, the closed loop 12 generates a clock signal of a period by delaying a signal by a period of time according to the first controlling current by all of the first current-controlled delay circuits 11.

The clock signal generated by the closed loop 12 is compared in phase with the reference signal by the phase comparator 15.

The charge pump 16 outputs current in response to the phase difference.

In the case where the clock signal advances in phase from the reference signal, the charge pump 16 pulls in the current.

On the other hand, in the case where the clock signal delays in phase from the reference signal, the charge pump 16 outputs current.

Consequently, the charging voltage of the capacitor of the loop filter 17 is adjusted so as to decrease the phase difference.

The first voltage-current conversion circuit 18 outputs the first controlling current corresponding to the charging voltage of the capacitor.

By the control described above, the PLL circuit 1 outputs a clock signal of a frequency synchronized with the reference signal.

The clock signal is stabilized to a state synchronized with the reference signal.

At this time, the first controlling current is stabilized to a desired current value.

After the clock signal of the PLL circuit 1 is stabilized, the modulation controlling section 22 starts on/off of the switching transistors 62 of the current DA converter 21, for example, based on interrupt processing by measurement time of a timer not shown.

The modulation controlling section 22 controls the on/off state of the switching transistors 62 so that the first controlling current and the spread spectrum current are supplied time-divisionally to the one first current-controlled delay circuit 11.

The modulation controlling section 22 carries out time-divisional changeover between the set value with which all switching transistors 62 are placed into an on state and the set value with which one or more of the switching transistors 62 are placed into an on state so as to be outputted to the current DA converter 21.

Further, the modulation controlling section 22 time-divisionally changes over a combination of on/off states of the switching transistors 62 so that a plurality of spread spectrum currents are supplied time-divisionally.

The modulation controlling section 22 carries out time-divisional changeover of the set value with which one or more of the switching transistors 62 are placed into an on state and outputs the set value to the current DA converter 21.

If the spread spectrum current is supplied in place of the first controlling current, then the delay time of a signal by the first current-controlled delay circuit 11 varies.

For example, in the case where the spread spectrum current is lower than the first controlling current, the delay time of a signal of the first current-controlled delay circuit 11 becomes long.

On the other hand, in the case where the spread spectrum current is higher than the first controlling current, the delay time of a signal by the first current-controlled delay circuit 11 becomes short.

Also the period and the frequency of the clock signal generated by the closed loop 12 are varied by variation of the delay time of the signal by the one first current-controlled delay circuit 11.

As described above, in the first embodiment, the first controlling current and the spread spectrum current are supplied time-divisionally to one of the first current-controlled delay circuits 11 which configure the closed loop 12.

Therefore, in the first embodiment, the closed loop 12 formed from a particular one or ones of the first current-controlled delay circuits 11 outputs a clock signal of a frequency different from that which is generated where the first controlling current is supplied to all of the first current-controlled delay circuits 11.

The closed loop 12 oscillates with a state in which the first controlling current is supplied to all of the first current-controlled delay circuits 11 and another state in which the spread spectrum current of a current value different from the first controlling current is supplied to a particular one or ones of the first current-controlled delay circuits 11.

As a result, the spectrum of the clock signal includes a spectrum of a desired frequency synchronized with the reference signal and another spectrum of another frequency displaced a little from the desired frequency.

The spectrum of the clock signal spreads.

As a result of the dispersion of the spectrum, the peak of the spectrum becomes lower.

The variation width of the frequency of the clock signal in the first embodiment is smaller than that in the case in which the spread spectrum current is supplied to all of the first current-controlled delay circuits 11 in the closed loop 12.

The resolution of the current DA converter 21 decreases by an amount corresponding to the number of stages of the first current-controlled delay circuits 11 in the closed loop 12. In the case where the number of stages is three, the resolution is reduced to one third.

The spread current generation section 19 can spread the spectrum by causing the frequency of the clock signal to time-divisionally fluctuate with the low resolution required for spectrum spreading irrespective of the range of the current adjustment.

As a result, the circuit scale of the current DA converter 21 of the spread current generation section 19 decreases.

<2. Comparative Example>

Configuration and Operation of the PLL Circuit 1 of a Comparative Example

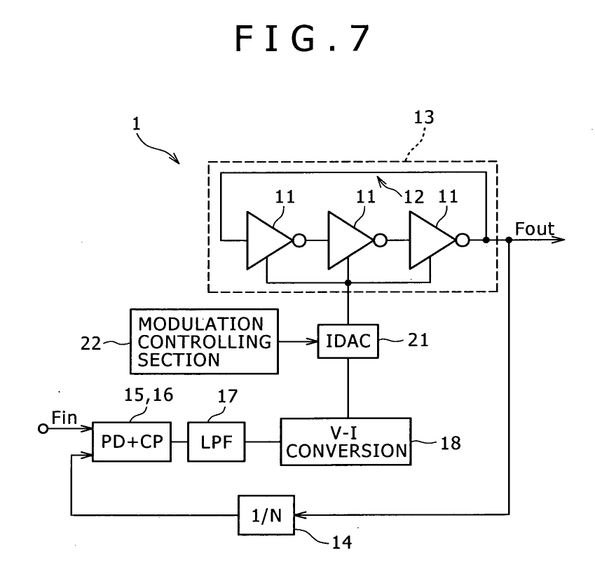

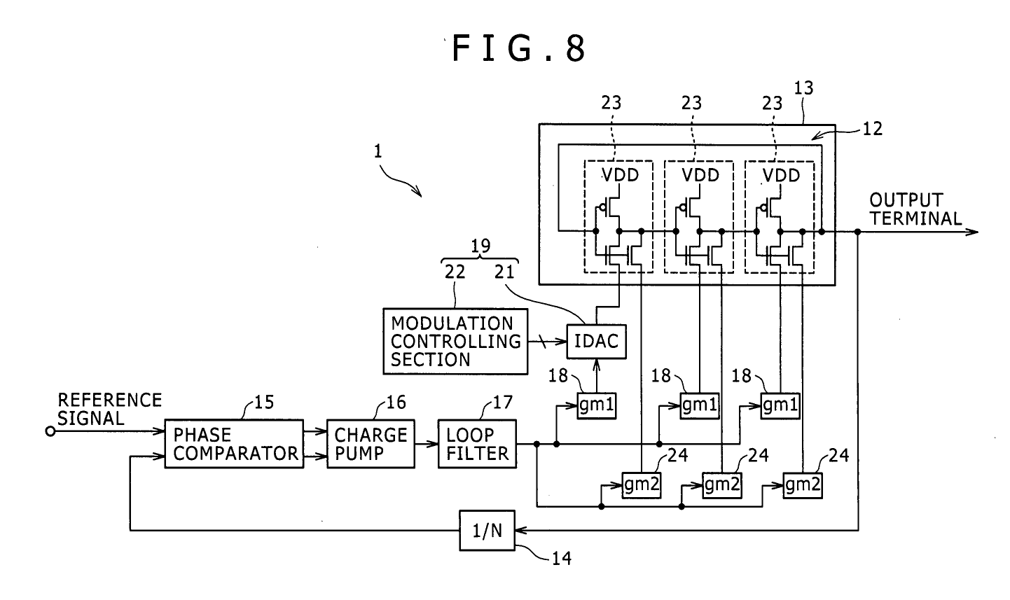

FIG. 7 shows a PLL circuit 1 of a comparative example.

Referring to FIG. 7, components of the PLL circuit 1 correspond to the components of that in the first embodiment.

In the PLL circuit 1 of the comparative example of

FIG. 1, the current DA converter 21 is connected to all of the first current-controlled delay circuits 11 which configure the closed loop 12.

Then, in the PLL circuit 1 of the comparative example, if the modulation controlling section 22 starts on/off control of the switching transistors 62 of the current DA converter 21, then the spread spectrum current is supplied to all of the first voltage-current conversion circuits 18.

The delay time of a signal by all of the first voltage-current conversion circuits 18 fluctuates.

As a result, in the PLL circuit 1 of the comparative example, the period and the frequency of the clock signal generated by the closed loop 12 fluctuate by a great amount while the resolution of the current DA converter 21 remains as it is.

The resolution of the current DA converter 21 becomes the resolution of the delay time as it is.

Therefore, in order for the PLL circuit 1 of the comparative example to cause the frequency of the clock signal to time-divisionally fluctuate with the low resolution required for spectrum spreading, the resolution of the current DA converter 21 must be made high.

The resolution of the current DA converter 21 must be set to a level with which a spectrum spreading effect is obtained.

Incidentally, the resolution of the current DA converter 21 depends upon the number of output side mirror circuits 63 and switching transistors 62.

Therefore, in order for the PLL circuit 1 of the comparative example to cause the frequency of the clock signal to fluctuate with the low resolution required for spectrum spreading, it is necessary to increase the number of output side mirror circuit 63 and switching transistor 62 of the current DA converter 21.

The number of the output side mirror circuits 63 and the switching transistors 62 must be increased to such a degree that the range from 0 to the first controlling current is divided by the low resolution required for spectrum spreading.

As a result, if it is tried to allow the PLL circuit 1 of the comparative example to achieve an effect of spectrum spreading while a great fluctuation of the oscillation frequency is suppressed, then the circuit scale of the current DA converter 21 becomes very great.

Particularly in the case where it is tried to generate a clock signal of a high frequency in recent years, since the oscillation frequency is high, the circuit scale becomes very great.

<3. Second Embodiment>

Configuration of the PLL Circuit 1

FIG. 8 shows a circuit configuration of a PLL circuit 1 according to a second embodiment.

Referring to FIG. 8, the PLL circuit 1 shown includes a ring oscillation section 13 including a closed loop 12 of a plurality of second current-controlled delay circuits 23. Further, the PLL circuit 1 includes a frequency dividing circuit 14, a phase comparator 15, a charge pump 16, a loop filter 17, a plurality of first voltage-current conversion circuits 18, a plurality of second voltage-current conversion circuits 24, and a spread current generation section 19.

The spread current generation section 19 includes a current DA converter 21 and a modulation controlling section 22.

In the PLL circuit 1 according to the second embodiment, spread spectrum current and second controlling current are supplied time-divisionally to a particular one or ones of the plural second current-controlled delay circuits 23 which configure the closed loop 12.

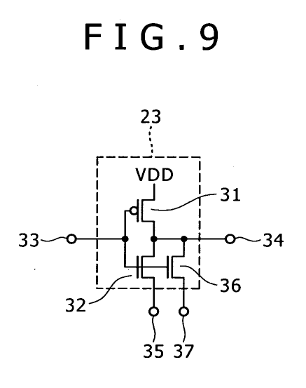

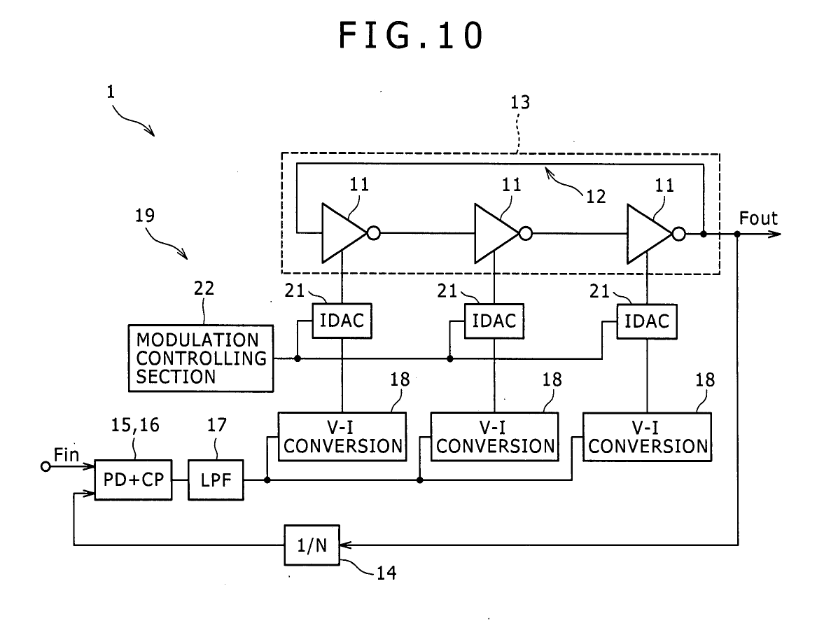

FIG. 9 shows a circuit configuration of a second current-controlled delay circuit 23 shown in FIG. 8.

Referring to FIG. 9, the second current-controlled delay circuit 23 shown includes a first transistor 31, a second transistor 32 and a third transistor 36. The first current-controlled delay circuit 11 has an input terminal 33, an output terminal 34, a first current terminal 35 and a second current terminal 37.

The third transistor 36 is, for example, an N channel MOS transistor.

The third transistor 36 is connected at the gate electrode thereof to the input terminal 33, at the source electrode thereof to the second current terminal 37 and at the drain electrode thereof to the output terminal 34.

The third transistor 36 is connected in parallel to the second transistor 32.

The third transistor 36 and the second transistor 32 form a CMOS structure together with the first transistor 31.

By a switching operation of the first transistor 31, second transistor 32 and third transistor 36, the second current-controlled delay circuit 23 inverts a signal inputted to the input terminal 33 and outputs the inverted signal from the output terminal 34.

The three second current-controlled delay circuits 23 are connected in series in the three stages to configure the closed loop 12 as seen in FIG. 8.

Each first voltage-current conversion circuit 18 is connected to the first current terminal 35 of the corresponding second current-controlled delay circuit 23.

First controlling current is supplied from the first voltage-current conversion circuit 18 to the second current-controlled delay circuit 23.

Each second voltage-current conversion circuit 24 includes a current transistor 51 similarly to the first voltage-current conversion circuits 18 shown in FIG. 5.

The second voltage-current conversion circuit 24 is connected to the second current terminal 37 of the second current-controlled delay circuit 23.

Second controlling current is supplied from the second voltage-current conversion circuit 24 to the corresponding second current-controlled delay circuit 23.

The current DA converter 21 is connected between one of the first voltage-current conversion circuits 18 and the first current terminal 35 of the second current-controlled delay circuit 23 corresponding to the first voltage-current conversion circuit 18.

Operation of the PLL Circuit 1

Now, operation of the PLL circuit 1 having the configuration described above is described.

In an initial state, the modulation controlling section 22 controls all of the switching transistors 62 of the current DA converter 21 to an on state to stabilize the clock signal of the PLL circuit 1.

After the clock signal of the PLL circuit 1 is stabilized, the modulation controlling section 22 starts on/off control of the switching transistors 62 of the current DA converter 21, for example, based on interrupt processing by measurement time of a timer not shown.

The modulation controlling section 22 controls on/off of the switching transistors 62 so that the first controlling current and the spread spectrum current are supplied time-divisionally to the one second current-controlled delay circuit 23.

Further, the modulation controlling section 22 controls the combination of on/off states of the switching transistors 62 so that a plurality of spread spectrum currents of different frequencies are supplied time-divisionally.

To the one first voltage-current conversion circuits 18, the spread spectrum current and the second controlling current are supplied time-divisionally. The delay time of a signal by the first voltage-current conversion circuits 18 fluctuates with respect to time.

By the fluctuation of the delay time of a signal by the one first voltage-current conversion circuit 18, also the period and the frequency of the clock signal generated by the closed loop 12 fluctuate.

The spectrum of the clock signal is spread suitably to the plural frequencies. The peak of the spectrum becomes lower.

As described above, in the second embodiment, the second controlling current is always supplied to the second current-controlled delay circuit 23 to which the first controlling current and the spread spectrum current are supplied time-divisionally.

Therefore, the current DA converter 21 in the second embodiment may be a current DA converter which can adjust part of the total controlling current which need be supplied to the second current-controlled delay circuit 23 in order to obtain a clock signal of a desired frequency.

The current DA converter 21 may not be configured such that it can adjust the current from 0 ampere to the total controlling current.

As a result, the current DA converter 21 in the second embodiment may be any current DA converter which can obtain a desired resolution within a range of fluctuation of the frequency necessitated to obtain a spectrum spreading effect. Thus, the circuit scale can be reduced even in comparison with that in the first embodiment.

<4. Third Embodiment>

Configuration of the PLL Circuit 1

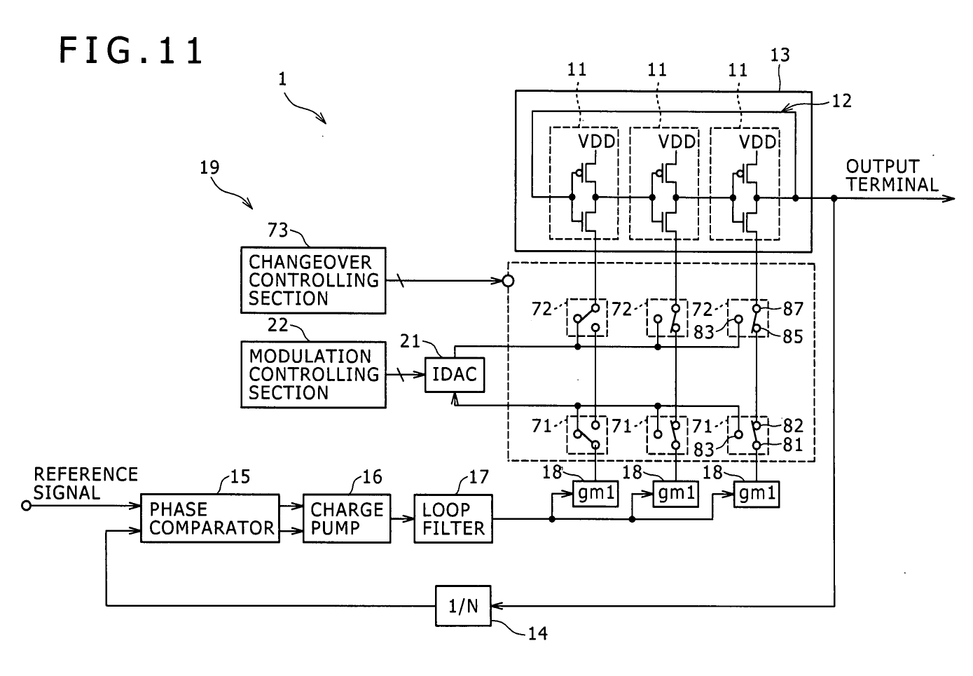

FIG. 10 schematically shows a PLL circuit 1 according to a third embodiment, and FIG. 11 shows a circuit configuration of the PLL circuit 1 of FIG. 10.

Referring to FIGS. 10 and 11, the PLL circuit 1 includes a ring oscillation section 13 including a closed loop 12 of a plurality of first current-controlled delay circuits 11. Further, the PLL circuit 1 includes a frequency dividing circuit 14, a phase comparator 15, a charge pump 16, a loop filter 17, a plurality of first voltage-current conversion circuits 18 and a spread current generation section 19.

The spread current generation section 19 includes a current DA converter 21, a modulation controlling section 22, a plurality of first changeover switches 71, a plurality of second changeover switches 72, and a changeover controlling section 73.

The PLL circuit 1 supplies spread spectrum currents time-divisionally in order part by part to the first current-controlled delay circuits 11 which configure the closed loop 12.

Consequently, at each timing, the delay time of a signal by a particular one or ones of the first current-controlled delay circuits 11 fluctuates.

The frequency of the clock signal generated by the ring oscillation section 13 varies delicately.

The spectrum of the clock signal spreads. Each first changeover switch 71 is a one-input two-output switch.

The first changeover switch 71 has one input terminal 81 and two output terminals 82 and 83.

The first changeover switch 71 selects one of the output terminals 82 and 83 and connects the particular output terminal 82 or 83 to the input terminal 81.

The first changeover switch 71 is connected at the input terminal 81 thereof to the corresponding first voltage-current conversion circuit 18.

The first changeover switch 71 is connected at the output terminal 82 thereof to the corresponding second changeover switch 72 and at the output terminal 83 thereof to the input terminal 64 of the current DA converter 21.

The second changeover switch 72 is a two-input one-output switch.

The second changeover switch 72 has two input terminals 85 and 86 and one output terminal 87.

The second changeover switch 72 selects one of the two input terminals 85 and 86 and connects the particular input terminal 85 or 86 to the output terminal 87.

The second changeover switch 72 is connected at the output terminal 87 thereof to the first current terminal 35 of the first current-controlled delay circuit 11.

The second changeover switch 72 is connected at the input terminal 85 thereof to the output terminal 82 of first changeover switch 71 and at the input terminal 86 thereof to the output terminal 65 of the current DA converter 21.

The changeover controlling section 73 is connected to the first changeover switches 71 and the second changeover switches 72.

The changeover controlling section 73 controls a changeover operation between the first changeover switches 71 and between the second changeover switches 72.

For example, the changeover controlling section 73 controls a changeover operation among a plurality of sets of a first changeover switch 71 and a second changeover switch 72 connected to each other such that one of the sets successively selects the current DA converter 21.

Operation of the PLL Circuit 1

In the PLL circuit 1 according to the third embodiment, the modulation controlling section 22 first controls all of the switching transistors 62 of the current DA converter 21 to an on state.

Further, the changeover controlling section 73 controls all of the first changeover switches 71 and the second changeover switch 72 to select each other.

In this state, the PLL circuit 1 starts an oscillation operation.

After the clock signal of the PLL circuit 1 is stabilized, the modulation controlling section 22 starts on/off control of the switching transistors 62 of the current DA converter 21, for example, based on interrupt processing by measurement time of a timer not shown.

The modulation controlling section 22 controls on/off of the switching transistors 62 so that the first controlling current and the spread spectrum current are supplied time-divisionally.

Further, the modulation controlling section 22 controls the combination of on/off states of the switching transistors 62 so that a plurality of spread spectrum currents of different frequencies are supplied time-divisionally.

Further, after the clock signal of the PLL circuit 1 is stabilized, the changeover controlling section 73 starts control of the first changeover switch 71 and the second changeover switch 72.

The changeover controlling section 73 controls the changeover operation so that one of the sets of a first changeover switch 71 and a second changeover switch 72 successively selects the current DA converter 21.

As described above, in the third embodiment, spread spectrum currents are supplied time-divisionally one by one in order to the first current-controlled delay circuits 11 which configure the closed loop 12.

Further, the spread spectrum current supplied to each first current-controlled delay circuit 11 is based on the first controlling current generated by the corresponding first voltage-current conversion circuits 18.

Here, a case is considered in which the spread spectrum current is supplied fixedly to one of the first current-controlled delay circuits 11 which configure the closed loop 12, for example, as in the case of the first embodiment.

In this instance, the delay characteristic of a particular one or ones of the first current-controlled delay circuits 11 sometimes disperses with respect to the delay characteristic of the other first current-controlled delay circuits 11.

Further, by the dispersion of the first voltage-current conversion circuits 18, the first controlling current of the same sometimes disperses with respect to the other first controlling currents.

As a result, there is the possibility that the spectrum may not spread in a desired manner. The spectrum may not possibly be spread suitably.

In contrast, in the present embodiment, the first current-controlled delay circuit 11 to which the spread spectrum current is supplied is successively changed over among the first current-controlled delay circuits 11 which configure the closed loop 12.

The spectrum spreads suitably without being influenced by a dispersion in delay characteristic or the like of the first current-controlled delay circuits 11.

The spectrum of the clock signal can be dispersed in a desired manner to suitably suppress the peak of electromagnetic radiation by the clock signal.

<5. Fourth Embodiment>

Configuration of the PLL Circuit 1

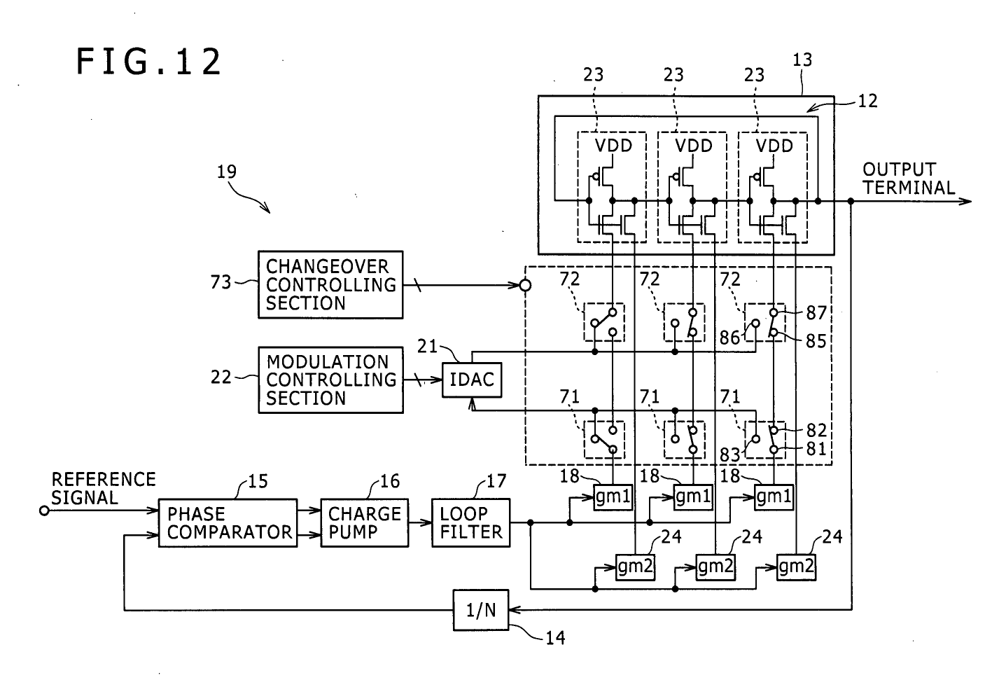

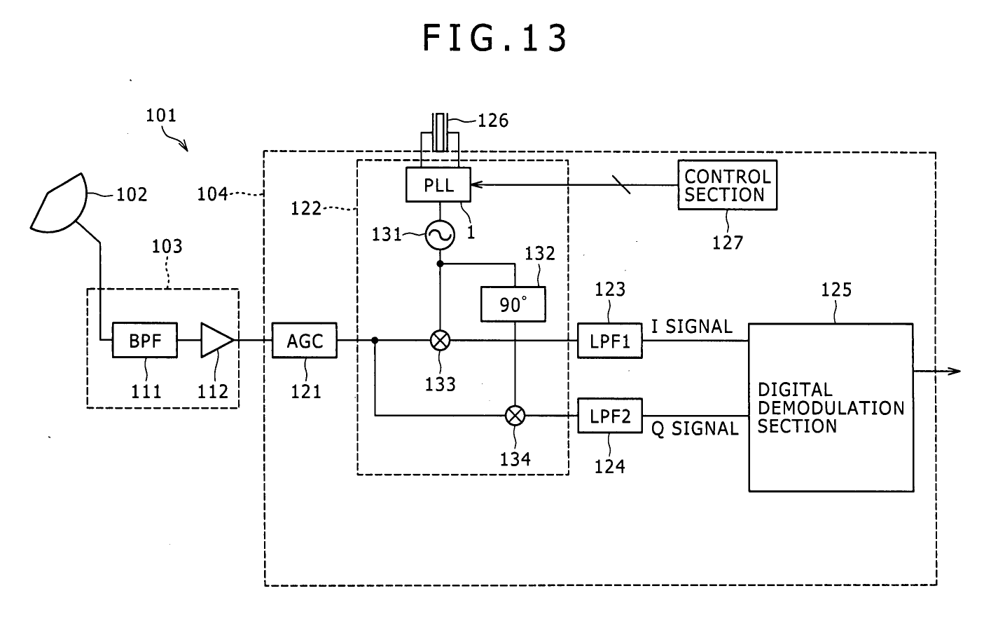

FIG. 12 shows a circuit configuration of a PLL circuit 1 according to the fourth embodiment.

Referring to FIG. 12, the PLL circuit 1 shown includes a ring oscillation section 13 which includes a plurality of second current-controlled delay circuits 23. Further, the PLL circuit 1 includes a frequency dividing circuit 14, a phase comparator 15, a charge pump 16, a loop filter 17, a plurality of first voltage-current conversion circuits 18, a plurality of second voltage-current conversion circuits 24, and a spread current generation section 19.

The spread current generation section 19 includes a current DA converter 21, a modulation controlling section 22, a plurality of first changeover switches 71, a plurality of second changeover switches 72, and a changeover controlling section 73.

Each first voltage-current conversion circuit 18 is connected to the input terminal 81 of the first changeover switch 71.

The first changeover switch 71 is connected at the output terminal 82 thereof to the input'terminal 85 of the second changeover switch 72 and at the output terminal 87 to the first current terminal 35 of the second current-controlled delay circuit 23.

First controlling current is supplied from the first voltage-current conversion circuit 18 to the corresponding second current-controlled delay circuit 23.

Each second voltage-current conversion circuit 24 is connected to the second current terminal 37 of the corresponding second current-controlled delay circuit 23.

The second controlling current is supplied from the second voltage-current conversion circuit 24 to the second current-controlled delay circuit 23.

Each first changeover switch 71 is connected at the output terminal 83 thereof to the input terminal 64 of the current DA converter 21.

Each second changeover switch 72 is connected at the input terminal 86 thereof to the output terminal 65 of the current DA converter 21.

Operation of the PLL Circuit 1

In the PLL circuit 1 according to the fourth embodiment, the modulation controlling section 22 first controls all of the switching transistors 62 of the current DA converter 21 to an on state.

Further, the changeover controlling section 73 controls all of the first changeover switches 71 and the second changeover switches 72 to select each other.

In this state, the PLL circuit 1 starts an oscillation operation.

After the clock signal of the PLL circuit 1 is stabilized, the modulation controlling section 22 starts on/off control of the switching transistors 62 of the current DA converter 21, for example, based on interrupt processing by measurement time of a timer not shown.

The modulation controlling section 22 controls on/off of the switching transistors 62 so that the first controlling current and the spread spectrum current are supplied time-divisionally.

Further, the modulation controlling section 22 controls the combination of on/off states of the switching transistors 62 so that a plurality of spread spectrum currents of different frequencies are supplied time-divisionally.

Further, after the clock signal of the PLL circuit 1 is stabilized, the changeover controlling section 73 starts control of the first changeover switches 71 and the second changeover switches 72.

The changeover controlling section 73 controls the changeover operation of the plural sets of a first changeover switch 71 and a second changeover switch 72 so that one of the sets selects the current DA converter 21 in order.

As described above, in the fourth embodiment, the spread spectrum current is supplied time-divisionally one by one in order to the second current-controlled delay circuits 23 which configure the closed loop 12.

Further, the spread spectrum current supplied to each of the second current-controlled delay circuits 23 is based on the first controlling current generated by the corresponding first voltage-current conversion circuits 18.

As a result, in the fourth embodiment, the spectrum can be spread suitably in comparison with an alternative case in which spread spectrum current is supplied fixedly to a particular one or ones of the second current-controlled delay circuits 23.

By a desired spectrum distribution, the peak of electromagnetic radiation by the clock signal can be suppressed suitably.

<6. Fifth Embodiment>

Configuration and Operation of the Broadcasting Signal Reception Apparatus 101

FIG. 13 shows a block configuration of a broadcasting signal reception apparatus 101 according to a fifth embodiment.

Referring to FIG. 13, the broadcasting signal reception apparatus 101 is an example of an electronic apparatus wherein a clock signal generated by the PLL circuit 1 is utilized for generation of a local signal.

The broadcasting signal reception apparatus 101 includes an antenna 102, an inputting circuit 103, and a tuner 104.

The antenna 102 maybe, for example, a parabola antenna. The antenna 102 receives broadcasting signals.

The broadcasting signals may be, for example, satellite broadcasting signals.

As satellite broadcasting signals which can be utilized in Japan, for example, signals repeated by a BS (Broadcast Satellite) broadcasting satellite and signals repeated by a CS (Communication Satellite) communication satellite are available.

The inputting circuit 103 is connected to the antenna 102.

The inputting circuit 103 includes a band-pass filter 111 and a high frequency amplifier 112.

The band-pass filter 111 extracts broadcasting band components from a signal received by the antenna 102. The band-pass filter 111 extracts, for example, signal components within a band from 950 to 2,150 MHz.

The high frequency amplifier 112 amplifies the signal components extracted by the band-pass filter 111.

The tuner 104 includes an AGC (Automatic Gain Controller) circuit 121, a reception circuit 122, a first low-pass filter 123, a second low-pass filter 124, a digital demodulation section 125, a quartz oscillator 126, and a control section 127.

The reception circuit 122 includes a PLL circuit 1, a local oscillator 131, a phase conversion circuit 132, a first mixer 133, and a second mixer 134.

The AGC circuit 121 is connected to the high frequency amplifier 112 of the inputting circuit 103.

The AGC circuit 121 automatically amplifies the amplified signal components to generate a reception signal of a fixed level.

The PLL circuit 1 is any of the PLL circuits 1 according to the first to fourth embodiments.

The PLL circuit 1 is connected to the quartz oscillator 126.

The PLL circuit 1 uses a signal generated by the quartz oscillator 126 as a reference signal to generate a clock signal synchronized with the reference signal.

The local oscillator 131 is connected to the PLL circuit 1.

The local oscillator 131 generates a local signal based on the clock signal generated by the PLL circuit 1.

The phase conversion circuit 132 is connected to the local oscillator 131.

The phase conversion circuit 132 displaces the phase of the local signal.

The first mixer 133 is connected to the AGC circuit 121 and the local oscillator 131.

The first mixer 133 mixes the reception signal inputted from the AGC circuit 121 and the local signal. Consequently, the frequency of the reception signal is converted.

The first low-pass filter 123 is connected to the first mixer 133.

The first low-pass filter 123 removes unnecessary high frequency components from the signal frequency-converted by the first mixer 133 to generate an I signal, that is, an in-phase signal.

The second mixer 134 is connected to the AGC circuit 121 and the phase conversion circuit 132.

The second mixer 134 mixes the reception signal inputted from the AGC circuit 121 and the local signal having a phase displaced by 90 degrees.

Consequently, the frequency of the reception signal is converted.

The second low-pass filter 124 is connected to the second mixer 134.

The second low-pass filter 124 removes unnecessary high frequency components from the signal frequency-converted by the second mixer 134 to generate a Q signal, that is, a quadrature signal.

By the processing of the reception circuit 122 described above, a baseband signal composed of the I signal and the Q signal is generated.

The digital demodulation section 125 is connected to the first low-pass filter 123 and the second low-pass filter 124. The digital demodulation section 125 digitally demodulates the I signal and the Q signal.

The digital demodulation section 125 thereby generates a digital streaming signal included in the broadcasting signal. As the digital streaming signal, an MPEG-TS (Moving Picture Expert Group-Transport Stream) signal and so forth are available.

The digital streaming signal is transmitted, for example, to a liquid crystal monitor connected to the broadcasting signal reception apparatus 101.

The liquid crystal monitor reproduces an audio data signal and a video data signal included in the digital streaming signal.

Consequently, an audio content and a video content included in the broadcasting signal can be reproduced.

Function of the PLL Circuit 1

In such a reception operation as described above, the control section 127 is connected to the PLL circuit 1 and outputs a control signal to the PLL circuit 1.

For example, if a broadcasting channel to be received is selected, then the control section 127 outputs a control signal to the PLL circuit 1 in order to generate a local signal corresponding to the broadcasting channel.

Consequently, the PLL circuit 1 oscillates a clock signal of a frequency in accordance with the control signal as a clock signal synchronized with the reference signal.

After the oscillation frequency is stabilized, the PLL circuit 1 varies the frequency of the clock signal delicately under the control of the modulation controlling section 22 or the changeover controlling section 73.

While the embodiments described above are preferred embodiments of the disclosed technology, the technology is not limited to the embodiments but can be modified or altered in various manners without departing from the spirit and scope of the technology.

For example, in the embodiments described above, the ring oscillation section 13 of the PLL circuit 1 includes a single closed loop 12 formed from the first current-controlled delay circuits 11 or 23 of three stages.

The closed loop 12 of the ring oscillation section 13 may otherwise include a first current-controlled delay circuit 11 or 23 of one stage or first current-controlled delay circuits 11 or 23 of five or more stages.

Or, the closed loop 12 may be configured from a combination of the first current-controlled delay circuits 11 or 23 and a delay circuit having fixed delay time.

Further, the ring oscillation section 13 may otherwise have a plurality of closed loops 12 such that one of the closed loops 12 to be used for oscillation of a clock signal can be changed over.

For example, outputs of first current-controlled delay circuits 11 or 23 of a plurality of stages may be individually connected to selectors such that a signal selected by the selectors is returned to the first current-controlled delay circuit 11 or 23 in the first stage.

In this instance, by changing over the signal selected by the selectors, the closed loop 12 to be used for oscillation of a clock signal can be changed over.

In the embodiments described above, the modulation controlling section 22 or the changeover controlling section 73 starts its control for spreading a spectrum after the oscillation frequency of the PLL circuit 1 is stabilized.

However, the modulation controlling section 22 or the changeover controlling section 73 may otherwise start its control upon starting of the PLL circuit 1.

The fifth embodiment uses the PLL circuit 1 in the broadcasting signal reception apparatus 101.

However, the PLL circuit 1 can be used also in such electronic apparatus as, for example, a transmitter, a receiver or an image processing apparatus.

In this instance, the clock signal of the PLL circuit 1 may be used for any other aim than generation of a local signal by the reception circuit 122.

For example, a transmission signal may be generated from the clock signal, or a timing signal synchronized with a synchronizing signal may be generated from the clock signal.

The present disclosure contains subject matter related to that disclosed in Japanese Priority Patent Application JP 2010-179383 filed in the Japan Patent Office on Aug. 10, 2010, the entire content of which is hereby incorporated by reference.

It should be understood by those skilled in the art that various modifications, combinations, sub-combinations and alterations may occur depending on design requirements and other factors in so far as they are within the scope of the appended claims or the equivalents thereof.

What is claimed is:

1. A clock generation circuit, comprising:
a current-controlled oscillation section including a plurality of delay circuits, which include a plurality of current-controlled delay circuits adapted to delay a signal by a delay amount corresponding to current supplied thereto, connected so as to form a closed loop and adapted to output a clock signal formed by said closed loop;
a phase controlling section including a comparator adapted to compare the clock signal with a reference signal and adapted to output controlling current, which varies so as to decrease the phase difference between the clock signal and the reference signal, to said current-controlled delay circuits; and
a spread current generation section adapted to supply spread spectrum current of a current value different from that of the controlling current in place of the controlling current to a particular one or ones of said current-controlled delay circuits.

2. The clock generation circuit according to claim 1, wherein the controlling current and the spread spectrum current are supplied time-divisionally to the particular one or ones of said current-controlled delay circuits.

3. The clock generation circuit according to claim 1, wherein said phase controlling section outputs a plurality of controlling currents adapted to be individually supplied to said current-controlled delay circuits, and
said spread current generation section is connected between the particular one or ones of said current-controlled delay circuits and said phase controlling section and time-divisionally supplies the controlling currents and the spread spectrum current to the particular one or ones of said current-controlled delay circuits.

4. The clock generation circuit according to claim 3, wherein
said phase controlling section outputs, as the controlling current to be supplied to each of said current-controlled delay circuits, first controlling current which varies so as to decrease the phase difference between the clock signal and the reference signal, and
said spread current generation section includes:
a current DA converter connected between the particular one or ones of said current-controlled delay circuits and said phase controlling section; and
a modulation controlling section adapted to control said current DA converter;
said modulation controlling section controlling the first controlling current and the spread spectrum current so as to be time-divisionally supplied to the particular one or ones of said current-controlled delay circuits which are connected to said current DA converter such that
the first controlling current or the spread spectrum current is supplied time-divisionally to the particular one or ones of said current-controlled delay circuits to which said spread current generation section is connected
while the first controlling current is supplied to the remaining ones of said current-controlled delay circuits to which said spread current generation section is not connected.

5. The clock generation circuit according to claim 3, wherein
said phase controlling section outputs, as the controlling current to be supplied to each of said current-controlled delay circuits, first controlling current which varies so as to decrease the phase difference between the clock signal and the reference signal and second controlling current, and
said spread current generation section includes:
a current DA converter connected between the particular one or ones of said current-controlled delay circuits and said phase controlling section; and
a modulation controlling section adapted to control said current DA converter;
said modulation controlling section time-divisionally supplying the first controlling current and the spread spectrum current to the particular one or ones of said current-controlled delay circuits which are connected to said current DA converter such that
the first controlling current or the spread spectrum current is supplied time-divisionally together with the second controlling current to the particular one or ones of said current-controlled delay circuits to which said spread current generation section is connected
while the first controlling current and the second controlling current are supplied to the remaining ones of said current-controlled delay circuits to which said spread current generation section is not connected.

6. The clock generation circuit according to claim 3, wherein said spread current generation section changes over the current-controlled delay circuit to which the spread spectrum current is supplied time-divisionally between said current-controlled delay circuits.

7. The clock generation circuit according to claim 3, wherein said spread current generation section includes:
a plurality of first changeover sections individually connected to said current-controlled delay circuits;
a plurality of second changeover sections individually connected to said first changeover sections and adapted to receive the controlling current as an input thereto from said phase controlling section;
a changeover controlling section adapted to control said first changeover sections and said second changeover sections;
a current DA converter connected to said first changeover sections and said second changeover sections and adapted to vary the controlling current inputted thereto from said second changeover sections at a ratio in accordance with a set value to generate spread spectrum current to be outputted to said first changeover sections; and
a modulation controlling section adapted to control said current DA converter;
said changeover controlling section carrying out changeover control of each of sets of said first changeover sections and said second changeover sections connected to each other such that said spread current generation section is time-divisionally connected in order to a particular one or ones of said current-controlled delay circuits,
said modulation controlling section time-divisionally changing over the set value of said current DA converter so that the controlling current and the spread spectrum current are generated time-divisionally.

8. The clock generation circuit according to claim 1, wherein said phase controlling section includes, in addition to said comparator adapted to compare the clock signal with the reference signal:
a charge pump adapted to output a voltage in response to an output signal of said comparator;
a loop filter adapted to smooth an output voltage of said charge pump; and
a plurality of voltage-current conversion circuits adapted to convert the output voltage smoothed by said loop filter into the controlling current.

9. An electronic apparatus, comprising:
a clock generation circuit adapted to generate a clock signal having a phase synchronized with that of a reference signal; and
an inputted section to which the clock signal is inputted;
said clock generation circuit including
a current-controlled oscillation section including a plurality of delay circuits, which include a plurality of current-controlled delay circuits adapted to delay a signal by a delay amount corresponding to current supplied thereto, connected so as to form a closed loop and adapted to output a clock signal formed by said closed loop,
a phase controlling section including a comparator adapted to compare the clock signal with a reference signal and adapted to output controlling current, which varies so as to decrease the phase difference between the clock signal and the reference signal, to said current-controlled delay circuits, and
a spread current generation section adapted to supply spread spectrum current of a current value different from that of the controlling current in place of the controlling current to a particular one or ones of said current-controlled delay circuits.
